(19) United States
(12) Patent Application Publication
(10) Pub. No.: US 2025/0338525 A1
(43) Pub. Date: Oct. 30, 2025

(54) IMPURE INDIUM PHOSPHIDE SEMICONDUCTOR SUBSTRATE

(71) Applicant: QUALCOMM Incorporated, San Diego, CA (US)

(72) Inventors: Ranadeep Dutta, Del Mar, CA (US); Jonghae Kim, San Diego, CA (US); Je-Hsiung Lan, San Diego, CA (US)

(21) Appl. No.: 18/649,443

(22) Filed: Apr. 29, 2024

(51) Int. Cl. H01L 29/737; H01L 29/08

(52) U.S. Cl. CPC H10D 10/861; H10D 10/841; H10D 62/137

(57) ABSTRACT

Aspects disclosed in the detailed description include an impure Indium Phosphide (InP) semiconductor substrate. Related apparatus and methods are also disclosed. In this regard, in some exemplary aspects disclosed herein, a semiconductor substrate comprising a silicon layer and an impure InP layer adjacent to the silicon layer. The impure InP layer may be epitaxially grown on a Silicon (Si) nanoridge base or directly bonded to the silicon layer after being epitaxially grown and cleaved. Utilizing an impure InP layer advantageously provides structural strength to be deployed in a 300 millimeter wafer process while achieving the electrical and thermal characteristic of InP it provides in a semiconductor substrate.

### TECHNICAL FIELD

The technology of the disclosure relates to fabricating a semiconductor substrate of Indium Phosphide (InP).

### BACKGROUND

Semiconductor substrates may be composed of various chemical compounds including Silicon (Si), Gallium Arsenide (GaAs), Silicon Germanium (SiGe), Indium Phosphide (InP), and the like. InP has the most desirable electrical and thermal characteristics. For example, studies have shown that a power amplifier formed on an InP substrate formed from a pure InP ingot has the lowest power consumption over a range of a number of antennas than power amplifiers fabricated in SiGe or Si. C. Desset et al., Globecom 2021. Additionally, a low noise amplifier (LNA) constructed on a pure InP substrate has the lowest thermal noise characteristic over an LNA constructed in silicon, gallium nitride (GaN), and GaAs. The advantageous electrical and thermal characteristics greatly benefit devices directed to niche applications such as radio frequency (RF) applications equal to or greater than 100 gigahertz (GHz), imaging radar applications, sensing applications, short range wireless connectivity applications, and photonic applications including lasers and modulators, for example. Since high volume manufacturing requires large wafers at least 300 millimeters (mm) in diameter to achieve higher yield at acceptable costs, use of pure InP substrates is currently limited to niche applications.

### SUMMARY OF THE DISCLOSURE

Aspects disclosed in the detailed description include an impure Indium Phosphide (InP) semiconductor substrate. Related apparatus and methods are also disclosed. In this regard, in some exemplary aspects disclosed herein, a semiconductor substrate is provided comprising a silicon layer and an impure InP layer adjacent to the silicon layer. The impure InP layer may be epitaxially grown on a Silicon nanoridge base or directly bonded to the silicon layer after being epitaxially grown and cleaved. Epitaxially growing the InP layer introduces impurities to the InP layer. Utilizing an impure InP layer advantageously provides structural strength to be deployed in a 300 millimeter (mm) wafer process while achieving the electrical and thermal characteristic of InP it provides in a semiconductor substrate.

In one aspect, a semiconductor substrate is provided. The semiconductor substrate comprises a silicon layer defining a first width of the semiconductor substrate in a first direction and an impure InP layer extending in the first direction along the first width of the semiconductor substrate, the impure InP layer adjacent to the silicon layer.

In another aspect, a method of fabricating a semiconductor substrate is provided. The method comprises providing a first silicon layer defining a first width of the semiconductor substrate in a first direction, and providing a first impure InP layer extending in the first direction along the first width of the semiconductor substrate, the first impure InP layer adjacent to the first silicon layer.

In another aspect a semiconductor substrate is provided. The semiconductor substrate comprises a means for providing a first silicon layer defining a first width of the semiconductor substrate in a first direction and a means for providing a first impure InP layer extending in the first direction along the first width of the semiconductor substrate, the first impure InP layer adjacent to the first silicon layer.

### BRIEF DESCRIPTION OF THE FIGURES

FIG. 1A is a first stage of fabricating a pure Indium Phosphide (InP) substrate on a 200-300 millimeter (mm) silicon wafer utilizing a pure InP ingot;

FIG. 1B is a second stage of fabricating a pure InP substrate on a 200-300 mm silicon wafer utilizing a pure InP ingot;

FIG. 1C is a third stage of fabricating a pure InP substrate on a 200-300 millimeter mm silicon wafer utilizing a pure InP ingot;

FIG. 2A is an exemplary semiconductor substrate including an impure InP layer;

FIG. 2B is an exemplary heterojunction transistor on a portion of the impure InP semiconductor substrate of FIG. 2A;

FIG. 3A is a portion of another exemplary impure InP semiconductor substrate;

FIG. 3B is an exemplary heterojunction transistor on the impure InP semiconductor substrate of FIG. 3A;

FIG. 4 is a flowchart illustrating an exemplary fabrication process for fabricating an impure InP semiconductor substrate, including, but not limited to, the impure InP semiconductor substrates in FIGS. 2A and 3A;

FIGS. 5A-5C is a flowchart of illustrating another exemplary fabrication process for fabricating an impure InP semiconductor substrate, including, but not limited to, the impure InP semiconductor substrates in FIGS. 2A and 3A;

FIGS. 6A-61 are exemplary fabrication stages during fabrication of the impure InP semiconductor substrate according to the fabrication process in FIGS. 5A-5C;

FIGS. 7A-7C is a flowchart of illustrating an exemplary fabrication process for fabricating a heterojunction transistor, including, but not limited to, the heterojunction transistors in FIGS. 2B and 3B deployed on the impure InP semiconductor substrates in FIGS. 2A and 3A;

FIGS. 8A-8G are exemplary fabrication stages during fabrication of the heterojunction transistor according to the fabrication process in FIGS. 7A-7C;

FIG. 9 is a block diagram of an exemplary wireless communications device that includes radio-frequency (RF) components deployed in an integrated circuit (IC) package, wherein the IC package includes an impure InP semiconductor substrate, including, but not limited to, the impure InP semiconductor substrates in FIGS. 2A and 3A and according to the exemplary fabrication processes in FIGS. 4, 5A-5C, and 7A-7C; and

FIG. 10 is a block diagram of an exemplary processor-based system that can include components deployed in an IC package, wherein the IC package includes an impure InP semiconductor substrate, including, but not limited to, the impure InP semiconductor substrates in FIGS. 2A and 3A and according to the exemplary fabrication processes in FIGS. 4, 5A-5C, and 7A-7C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise. The term “directly adjacent” as used herein means adjoining something as shown in the Figures.

Aspects disclosed in the detailed description include an impure Indium Phosphide (InP) semiconductor substrate. Related apparatus and methods are also disclosed. In this regard, in some exemplary aspects disclosed herein, a semiconductor substrate is provided comprising a silicon layer and an impure InP layer adjacent to the silicon layer. The impure InP layer may be epitaxially grown on a Silicon nanoridge base or directly bonded to the silicon layer after being epitaxially grown and cleaved. Epitaxially growing the InP layer introduced impurities to the InP layer. Utilizing an impure InP layer advantageously provides structural strength to be deployed in a 300 millimeter (mm) wafer process while achieving the electrical and thermal characteristic of InP it provides in a semiconductor substrate.

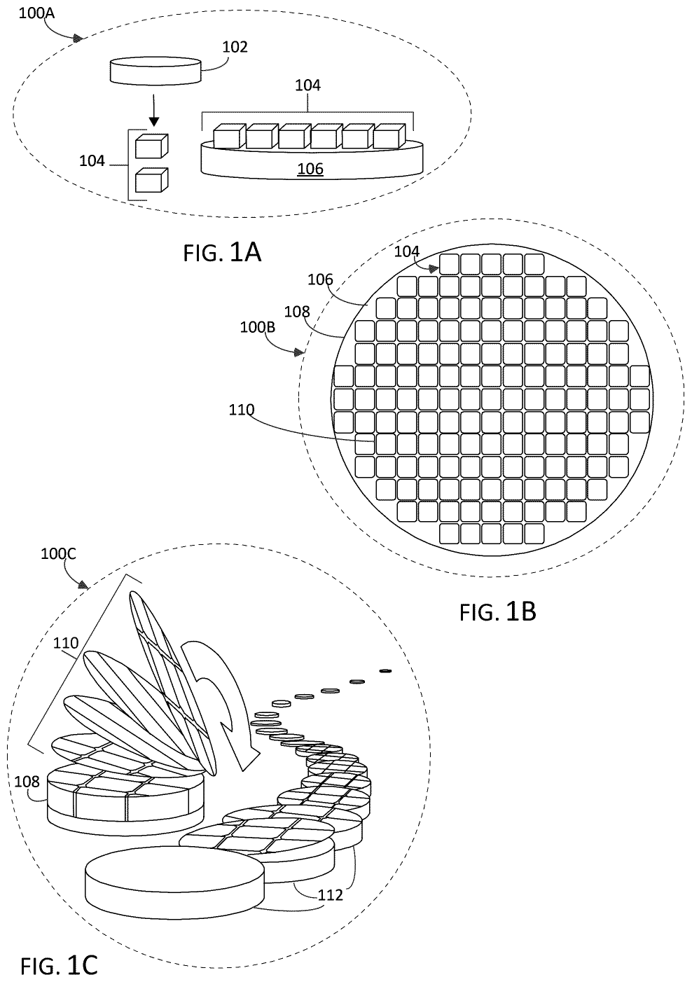

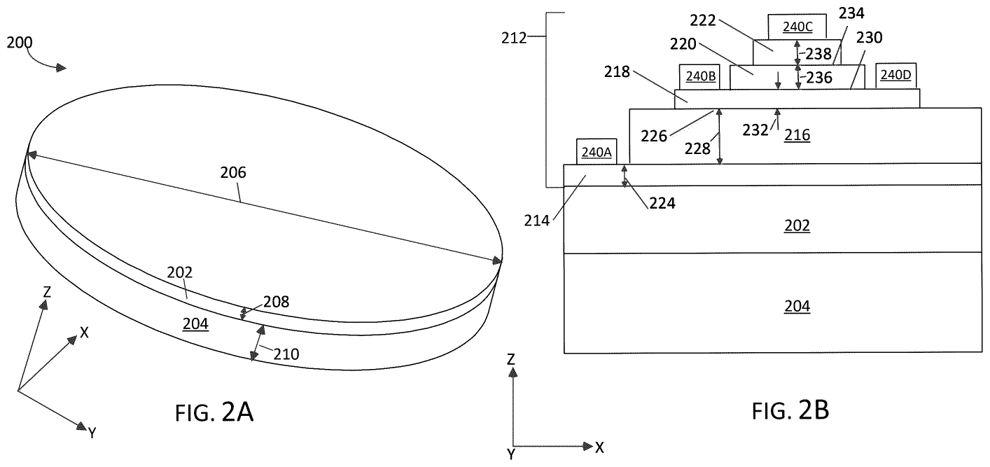

Before discussing exemplary aspects starting at FIG. 2A, a conventional approach to fabricating an InP substrate on a 200-300 millimeter (mm) silicon wafer utilizing a pure InP ingot is discussed. In this regard, FIG. 1A is a first stage 100A of fabricating a pure InP substrate on a 200-300 mm silicon wafer utilizing pure InP. The first stage 100A includes cutting small cylindrical wafers from a pure InP ingot 102 that is no more than 100-150 mm in diameter. The pure InP ingot 102 is sourced through a high temperature modified Czochralski process and is limited to 100-150 mm diameter because of the brittle nature of pure InP. Utilizing larger diameter InP ingots and slicing wafers from larger diameter InP ingots would be prohibitively expensive due to high rates of wafer breakage during the slicing process. The first stage 100A also includes singulating enough individual pure InP dies 104 from the multiple small cylindrical wafers to span a large silicon 200-300 mm wafer 106. During the singulating sub-process, undesirable thread dislocations propagate on each InP die's periphery negatively impacting the thermal and electrical characteristics of each die. The individual InP dies 104 are bonded to the large silicon 200-300 mm wafer 106 to form a pseudo donor 108 of substrates (FIG. 1B). The large silicon 200-300 mm wafer 106 is used as a carrier for the rest of the fabricating process.

FIG. 1B is a second stage 100B of fabricating a pure InP substrate on a 200-300 mm Si wafer utilizing the pure InP ingot 102. At stage 100B, the pseudo donor 108 of substrates includes isolating the bonded InP dies 104.

FIG. 1C is a third stage 100C of fabricating a pure InP substrate on a 200-300 mm silicon wafer utilizing a pure InP ingot. At stage 100C, the pseudo donor 108 of substrates is smart cut into multiple individual pure InP substrates 110 that are 200-300 mm in diameter, each of which are then bonded to a corresponding 200-300 mm silicon substrate 112. Because of the formation of defects, the electrical integrity of each smart cut off the pseudo donor decreases. As a result, the number of smart cuts of the donor substrate is limited to around 5 times.

As noted above, a pure InP substrate formed by the fabrication process described in FIGS. 1A-1C requires a pure InP ingot which is limited in diameter to 100-150 mm due to the brittle nature of pure InP and does not match today's high volume production fabrication which requires 300 mm wafers to achieve acceptable product yield at reasonable costs. As a result, the fabrication process described in FIGS. 1A-1C is expensive due to several factors including reliability yields due to threading dislocations at the edge of each singulated InP die and the limited number of smart cuts available off the pseudo donor.

Accordingly, in this regard, FIG. 2A is an exemplary semiconductor substrate 200 including an impure InP layer 202. The semiconductor substrate 200, also referred to as an impure InP semiconductor substrate 200, is in wafer form as illustrated in FIG. 2A. The impure InP semiconductor substrate 200 includes a silicon layer 204 defining a first width 206 of the impure InP semiconductor substrate 200 in a first, horizontal direction (X-, Y-axes direction) and the impure InP layer 202 extending in the first direction along the first width 206. If the semiconductor substrate 200 is singulated into multiple dies, the first width 206 of the impure InP layer 202 would be the same width as the silicon layer 204 defined by the width of the singulated dies. The impure InP layer 202 is adjacent to the silicon layer 204 and, in particular, directly adjacent to the silicon layer 204. The impure InP layer 202 comprises on the order of 10¹⁴ contaminants per cubic centimeter (cm³) and may have a thickness 208 in a second, vertical direction (Z-axis direction) between 10-20 micrometers (μm). The on the order of 10¹⁴ contaminants per cm³ comprise one or more elements or compounds selected from a group including oxygen, carbon, and hydrides. The first width 206 of the impure InP semiconductor substrate 200, when in wafer form, is at least 300 mm. The impure InP layer 202 is bonded to the silicon layer 204. The impure InP layer 202 may be bonded to the silicon layer 204 after oxidizing the Si surface or InP or after the Si is coated with organic monolayers such as thiol-based self assembled monolayer (SAM). The silicon layer 204 has a second width 210 in the second direction (Z-axis direction) of approximately 100 μm. The impure InP semiconductor substrate 200 can be a foundation upon which to support heterojunction transistors.

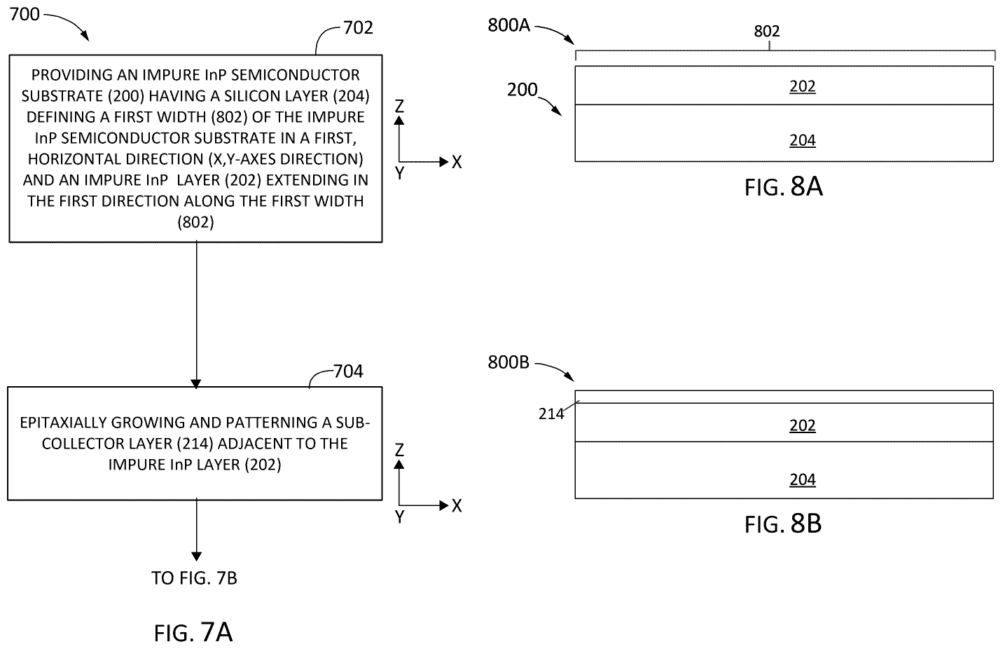

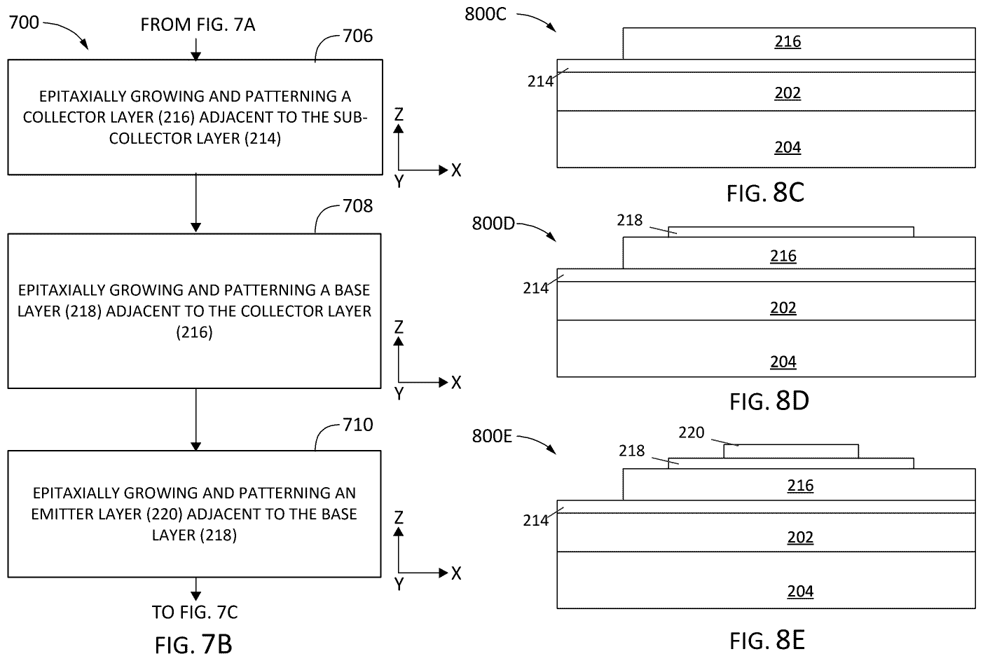

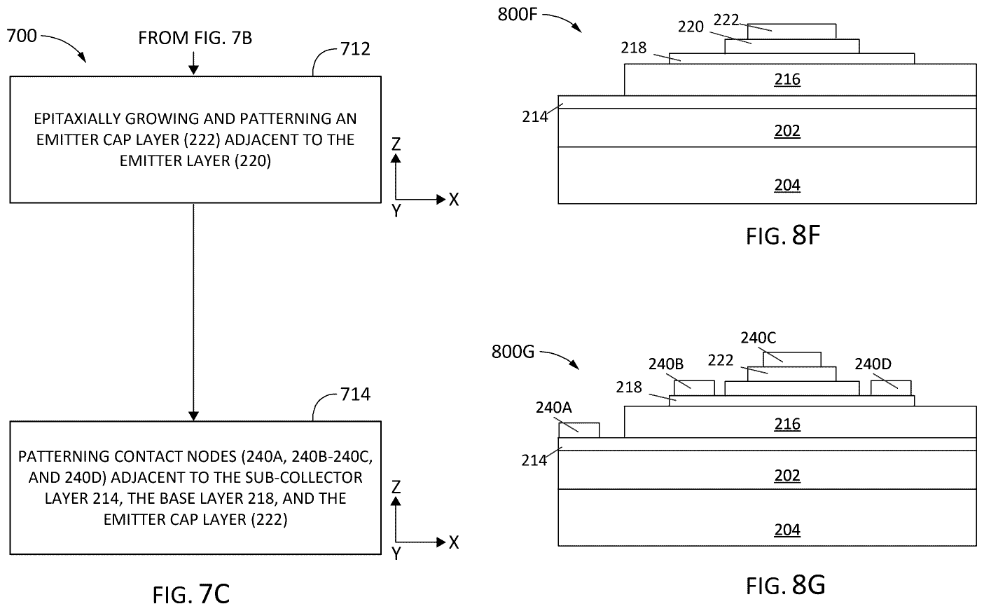

Accordingly, FIG. 2B is an exemplary heterojunction transistor 212 on a portion of the impure InP semiconductor substrate 200 of FIG. 2A. For example, the exemplary heterojunction transistor 212 may be disposed on a die cut from the impure InP semiconductor substrate 200 which is shown in wafer form in FIG. 2A. Common elements between FIG. 2B and in FIG. 2A are shown with common element numbers. The heterojunction transistor 212 includes a sub-collector layer 214 adjacent to the impure InP layer 202, a collector layer 216 adjacent to the sub-collector layer 214, a base layer 218 adjacent to the collector layer 216, an emitter layer 220 adjacent to the base layer 218, and an emitter cap layer 222 adjacent to the emitter layer 220. The sub-collector layer 214 includes indium gallium arsenide (InGaAs) and is N doped at a concentration between 5×10¹⁹ to 1×10²⁰ cm³. The sub-collector layer 214 has a thickness 224 in the second, vertical direction (Z-axis direction) of around 10 nanometers (nm). The collector layer 216 includes InP and has a top surface 226. Under the top surface 226, the collector layer 216 has a shallow pulse region N doped at a concentration of around 5×10¹⁸ cm³ for ohmic contact. Under the shallow pulse region, the collector layer 216 is N doped at a concentration of around 5×10¹⁶ to 1×10¹⁷ cm³. The collector layer 216 has a thickness 228 in the second, vertical direction (Z-axis direction) of around 70-150 nm including the thickness of the shallow pulse region of around 3-5 nm in the second, vertical direction. The base layer 218 includes InGaAs or gallium arsenide antimonide (GaAsSb) and has a top surface 230. The base layer 218 has been P graded doped from a concentration of around 1×10²⁰ cm³ from the top surface 230 to 5×10¹⁹ cm³ continuing down the second, vertical direction from the top surface 230. The base layer 218 has a thickness 232 in the second, vertical direction (Z-axis direction) of around 25-35 nm. The emitter layer 220 is InP and has a top surface 234. The emitter layer 220 has been N graded doped from a concentration of around 5×10¹⁹ cm³ from the top surface 234 for ohmic contact to 2×10¹⁸ cm³ continuing down the second, vertical direction from the top surface 234. The emitter layer 220 has a thickness 236 in the second, vertical direction (Z-axis direction) of around 30 nm. The emitter cap layer 222 is InGaAs. The emitter cap layer 222 has been N doped to around a concentration between 5×10¹⁹ cm³ and 1×10²⁰ cm³. The emitter cap layer 222 has a thickness 238 in the second, vertical direction (Z-axis direction) of around 10 nm. Contact nodes 240A-240D provide electrical connectivity for circuits to the heterojunction transistor 212. Contact node 240A provides electrical connectivity to the sub-collector layer 214. Contact nodes 240B, 240D provide electrical connectivity to the base layer 218. Contact node 240C provides electrical connectivity to the emitter cap layer 222. The N-type dopants described above are silicon. The P-type dopants described above are carbon. The contact nodes 240A-240D can be any one element individually or a combination of any set of the following elements including gold (Au), platinum (Pt), titanium (Ti), or tungsten (W). A fabrication process for fabricating a heterojunction transistor on an impure InP semiconductor substrate will be discussed in more detail in connection with FIGS. 7A-7C.

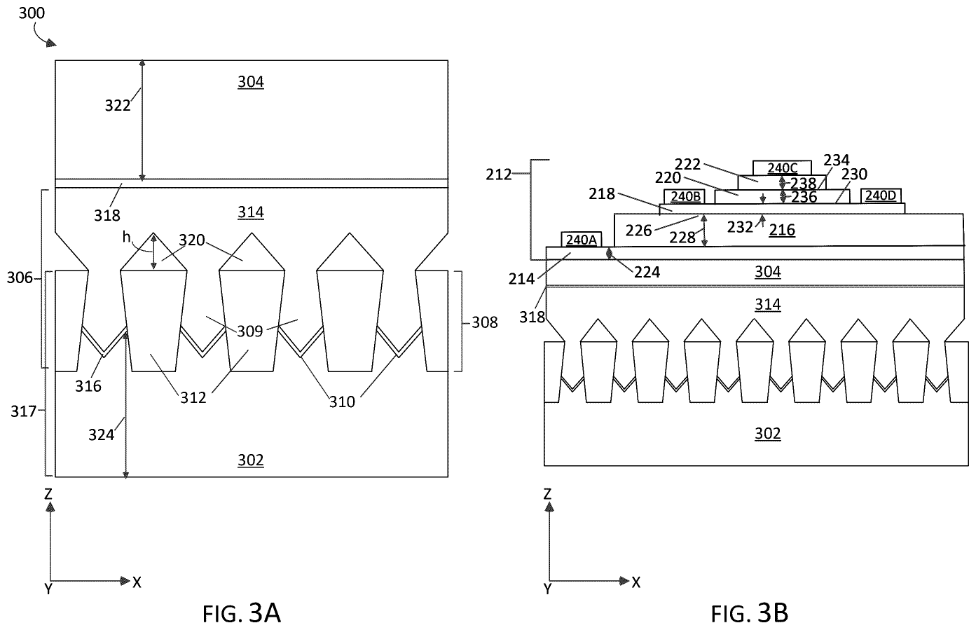

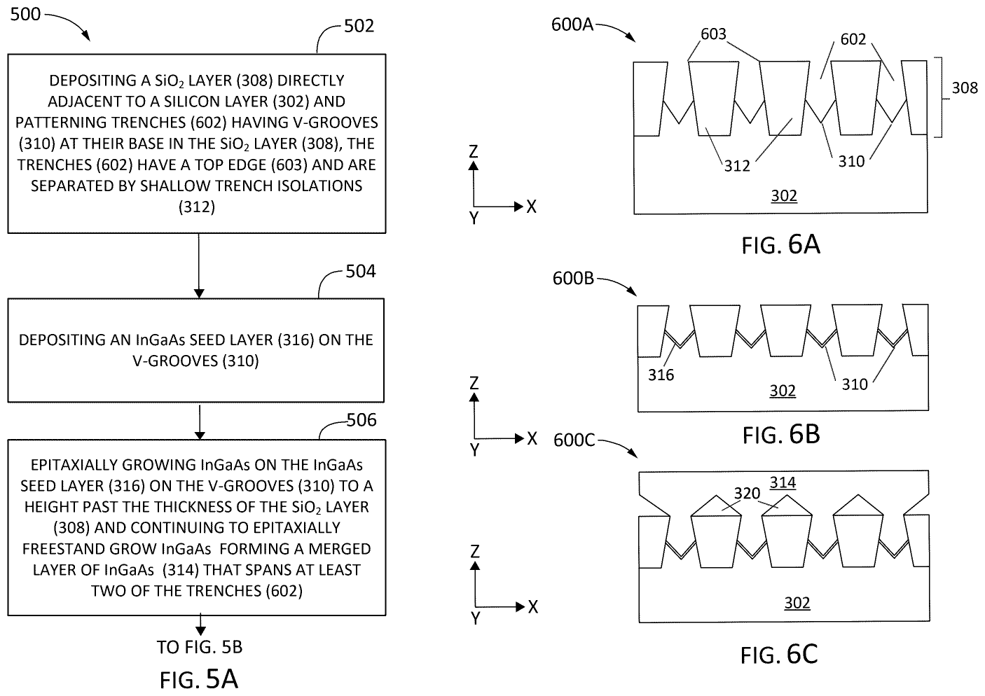

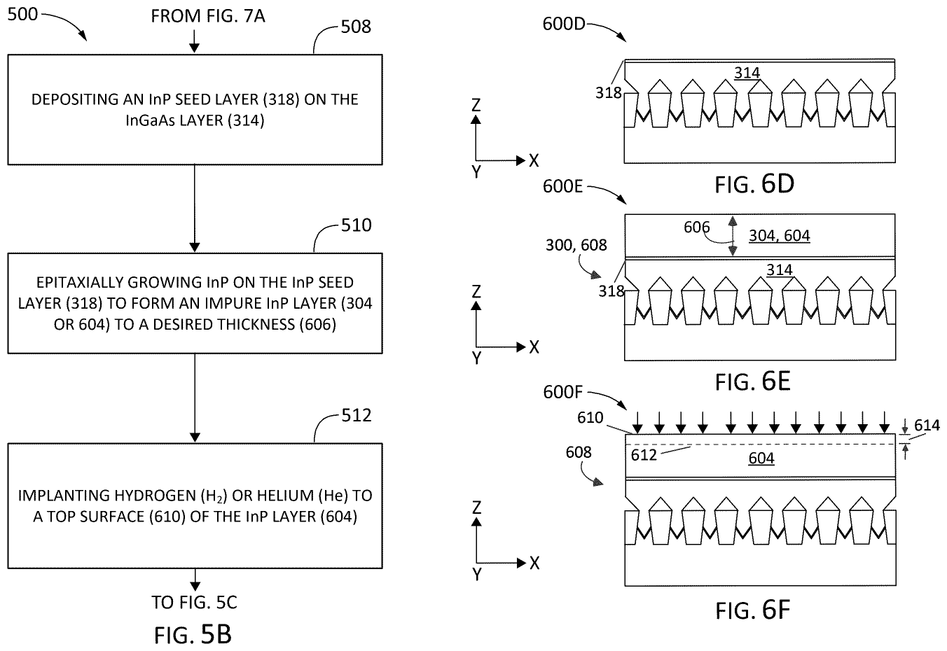

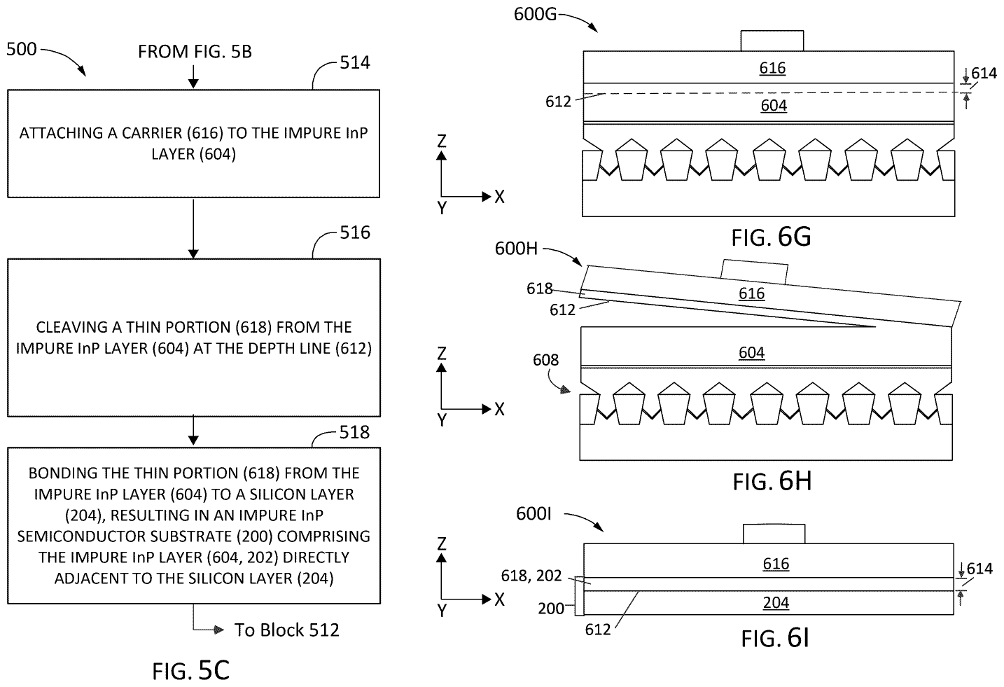

FIG. 3A is a portion of a another exemplary impure InP semiconductor substrate 300. The impure InP semiconductor substrate 300 includes a silicon layer 302 defining a first width of the impure InP semiconductor substrate 300 in a first direction and an impure InP layer 304 extending in the first direction along the first width. The impure InP layer 304 is adjacent to the silicon layer 302. The impure InP semiconductor substrate 300 includes an intermediate layer 306 between the silicon layer 302 and the impure InP layer 304. The intermediate layer 306 includes a silicon dioxide (SiO₂) layer 308 comprising a plurality of trenches 309 having a plurality of V-grooves 310 at their base separated by a plurality of shallow trench isolations 312, and an InGaAs layer 314 adjacent to the SiO₂ layer 308 and grown in the plurality of V-grooves 310. The plurality of V-grooves 310 are along a 111 Miller indices plane of the silicon layer 302. As will be discussed in connection with the fabrication process described in FIGS. 5A-5C, the InGaAs layer 314 is epitaxially grown on an InGaAs seed layer 316 deposited on the V-grooves 310 and continually grown in a freestanding fashion to form a merged layer of InGaAs. A silicon nanoridge foundation 317 refers to the silicon layer 302 and the SiO₂ layer 308 which includes the plurality of trenches 309 having the plurality of V-grooves 310 at their bases separated by the plurality of shallow trench isolations 312.

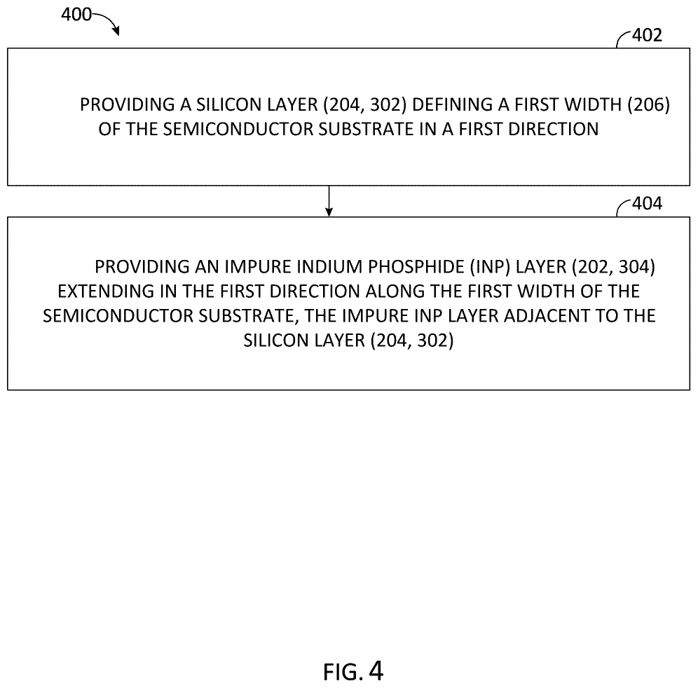

The impure InP layer 304 has been epitaxially grown on a InP seed layer 318 which was deposited on the InGaAs layer 314. The fabrication process of the impure InP semiconductor substrate 300 will be discussed in more detail in connection with FIGS. 4 and 5A-5C. A side effect of growing InGaAs to form the InGaAs layer 314 is the formation of tiny air pockets 320 (shown as triangles in FIG. 3A). These tiny air pockets 320 will be discussed in connection to the corresponding fabrication process in FIGS. 5A-5C.

The impure InP layer 304 comprises on the order of 10¹⁴ contaminants per cm³ and may have a thickness 322 between 10-20 micrometers (μm). The first width of the impure InP semiconductor substrate 300, when in wafer form, is at least 300 mm. The silicon layer 302 has a second width 324 in the second direction of approximately 100 μm. The impure InP semiconductor substrate 300 can be a foundation upon which to support heterojunction transistors.

In this regard, FIG. 3B illustrates the exemplary heterojunction transistor 212 of FIG. 2B on the impure InP semiconductor substrate 300 of FIG. 3A. Common elements between FIGS. 2B and 3A and in FIG. 3B are shown with common element numbers.

An impure InP semiconductor substrate including, but not limited to, the impure InP semiconductor substrates 200 and 300 in FIGS. 2A and 3A can be fabricated by different fabrication processes. FIG. 4 is a flowchart illustrating an exemplary fabrication process 400 of fabricating the impure InP semiconductor substrates 200, 300 in FIGS. 2A and 3A wherein the impure InP semiconductor substrates 200, 300 include an impure InP layer adjacent to a silicon layer. In this regard, a first exemplary step for fabricating an impure InP semiconductor substrate includes providing a silicon layer 204, 302 defining a first width of the semiconductor substrate in a first direction (block 402 in FIG. 4). The next step in the fabrication process 400 can include providing an impure InP layer 202, 304 extending in the first direction along the first width of the semiconductor substrate, the impure InP layer 202, 304 adjacent to the silicon layer 204, 302 (block 404 in FIG. 4).

Other fabrication processes can also be employed to fabricate an impure InP semiconductor substrate including, but not limited to, the exemplary semiconductor substrates 200, 300 in FIGS. 2A and 3A. In this regard, FIGS. 5A-5C is a flowchart of illustrating another exemplary fabrication process 500 for fabricating an impure InP semiconductor substrate, including, but not limited to, the impure InP semiconductor substrates 200, 300 in FIGS. 2A and 3A. FIGS. 6A-61 are exemplary fabrication stages during fabrication of the impure InP semiconductor substrates according to the fabrication process 500 in FIGS. 5A-5C. Blocks 502-510 are followed to create the exemplary impure InP semiconductor substrate 300 shown in FIG. 3A. Blocks 502-518 are followed to create the exemplary impure InP semiconductor substrate 200 shown in FIG. 2A.

In this regard, as shown in fabrication stage 600A in FIG. 6A, an exemplary step in the fabrication process 500 is depositing a SiO₂ layer 308 directly adjacent to a silicon layer 302 and patterning trenches 602 having V-grooves 310 at their bases in the SiO₂ layer 308, the trenches 602 have a top edge 603 and are separated by shallow trench isolations 312 (block 502 in FIG. 5A). As shown in fabrication stage 600B in FIG. 6B, a next step in the fabrication process 500 can include depositing an InGaAs seed layer 316 on the V-grooves 310 (block 504 in FIG. 5A). Please note that growing an InP layer directly on a silicon layer would result in many thread disclocations impacting the electrical and thermal conductivity of the InP layer. As shown in fabrication stage 600C in FIG. 6C, a next step in the fabrication process 500 can include epitaxially growing InGaAs on the InGaAs seed layer 316 on the V-grooves 310 to a height past the thickness of the SiO₂ layer 308 and continuing to epitaxially freestand grow the InGaAs forming a merged layer 314 of InGaAs that spans at least two of the trenches 602 (block 506 in FIG. 5A). Unlike conventional approaches of fabricating heterojunction transistors on a silicon nanoridge foundation where a much thicker SiO₂ layer is used to isolate each transistor and InGaAs is grown within trenches having V-grooves at their base, the freestanding growing of InGaAs means growing the InGaAs in each of the V-groove based trenches beyond a top surface of the SiO₂ layer to a point the InGaAs merges from the trenches to form a layer and beyond that point to a desired thickness. A side effect of growing InGaAs to form the InGaAs layer 314 is the formation of tiny air pockets 320 having a height, h, around 100 nm. These tiny air pockets 320 can be filled with SiO₂ while still epitaxially freestand growing the InGaAs by using another thin layer of a SiO₂ template having a thickness of about 50 nm adjacent to SiO₂ layer 308 during fabrication.

As shown in fabrication stage 600D in FIG. 6D, a next step in the fabrication process 500 can include depositing an InP seed layer 318 on the InGaAs layer 314 (block 508 in FIG. 5B). As shown in fabrication stage 600E in FIG. 6E, a next step in the fabrication process 500 can include epitaxially growing InP on the InP seed layer 318 to form an impure InP layer 304, 604 to a desired thickness 606 (block 510 in FIG. 5B). If the desired thickness 606 is 10-20 μm, the impure InP semiconductor substrate 300 has been completed with the impure InP layer 304. Otherwise, the impure InP layer 604 is epitaxially grown to a desired thickness 606 of around 100 μm and a donor of substrates 608 has been fabricated. As shown in fabrication stage 600F in FIG. 6F, a next step in the fabrication process 500 can include implanting hydrogen (H₂) or helium (He) to a top surface 610 of the impure InP layer 604. Doing so impacts the lattice structure of the impure InP layer 604 at a depth line 612 having a height 614 between 10-20 μm for subsequent cleaving. (block 512 in FIG. 5B). As shown in fabrication stage 600G in FIG. 6G, a next step in the fabrication process 500 can include attaching a carrier 616 to the impure InP layer 604 (block 514 in FIG. 5C). As shown in fabrication stage 600H in FIG. 6H, a next step in the fabrication process 500 can include cleaving a thin portion 618 from the impure InP layer 604 at the depth line 612 (block 516 in FIG. 5C). As shown in fabrication stage 6001 in FIG. 61, a next step in the fabrication process 500 can include bonding the thin portion 618 from the impure InP layer 604 to a silicon layer 204, resulting in an impure InP semiconductor substrate 200 comprising the impure InP layer directly adjacent to the silicon layer 204 (block 518 in FIG. 5C). The donor of substrates 608 can be re-used to cleave additional thin portions off of the impure InP layer 604 by proceeding to block 512. The cycle of blocks 512-518 may continue depending on the desired thickness 606 of the impure InP layer 604. Utilizing an impure InP layer, such as the impure InP layer 604, which is not a collection of singulated InP dies bonded to a carrier as discussed in FIGS. 1A-1C, threading dislocations at the edges of the singulated InP dies can be avoided.

Means for epitaxially growing InGaAs and InP to form the InGaAs layer 314 and the impure InP layer 304, respectively, include metalorganic chemical vapor deposition (MOCVD) or molecular beam epitaxy (MBE). Means for patterning the trenches 602 having the V-grooves 310 at their bases in the SiO₂ layer 308 include photolithography and etching.

FIGS. 7A-7C is a flowchart of illustrating an exemplary fabrication process 700 for fabricating a heterojunction transistor, including, but not limited to, the heterojunction transistor 212 in FIGS. 2B and 3B deployed on the impure InP semiconductor substrates 200 and 300 in FIGS. 2A and 3A. FIGS. 8A-8G arc exemplary fabrication stages during fabrication of the heterojunction transistor according to the fabrication process in FIGS. 7A-7C. The fabrication process 700 will be discussed with reference to the impure InP semiconductor substrate 200 in FIG. 2A for convenience but is equally applicable to the impure InP semiconductor substrate 300 in FIG. 3A. In this regard, as shown in fabrication stage 800A in FIG. 8A, an exemplary step in the fabrication process 700 is providing an impure InP semiconductor substrate 200 having a silicon layer 204 defining a first width 802 of the impure InP semiconductor substrate in a first, horizontal direction (X-, Y-axes direction) and an impure InP layer 202 extending in the first direction along the first width 802 (block 702 in FIG. 7A). As shown in fabrication stage 800B in FIG. 8B, a next step in the fabrication process 700 can include epitaxially growing and patterning a sub-collector layer 214 adjacent to the impure InP layer 202 (block 704 in FIG. 7A).

As shown in fabrication stage 800C in FIG. 8C, a next step in the fabrication process 700 can include epitaxially growing and patterning a collector layer 216 adjacent to the sub-collector layer 214 (block 706 in FIG. 7B). As shown in fabrication stage 800D in FIG. 8D, a next step in the fabrication process 700 can include epitaxially growing and patterning a base layer 218 adjacent to the collector layer 216 (block 708 in FIG. 7B). As shown in fabrication stage 800E in FIG. 8E, a next step in the fabrication process 700 can include epitaxially growing and patterning an emitter layer 220 adjacent to the base layer 218 (block 710 in FIG. 7B).

As shown in fabrication stage 800F in FIG. 8F, a next step in the fabrication process 700 can include epitaxially growing and patterning an emitter cap layer 222 adjacent to the emitter layer 220 (block 712 in FIG. 7C). As shown in fabrication stage 800G in FIG. 8G, a next step in the fabrication process 700 can include patterning a contact nodes 240A, 240B-240C, and 240D adjacent to the sub-collector layer 214, the base layer 218, and the emitter cap layer 222, respectively (block 714 in FIG. 7C).

Means for epitaxially growing the individual layers that form the heterojunction transistor 212 include metalorganic chemical vapor deposition (MOCVD) or molecular beam epitaxy (MBE). Means for patterning the individual layers that form the heterojunction transistor 212 include photolithography and etching.

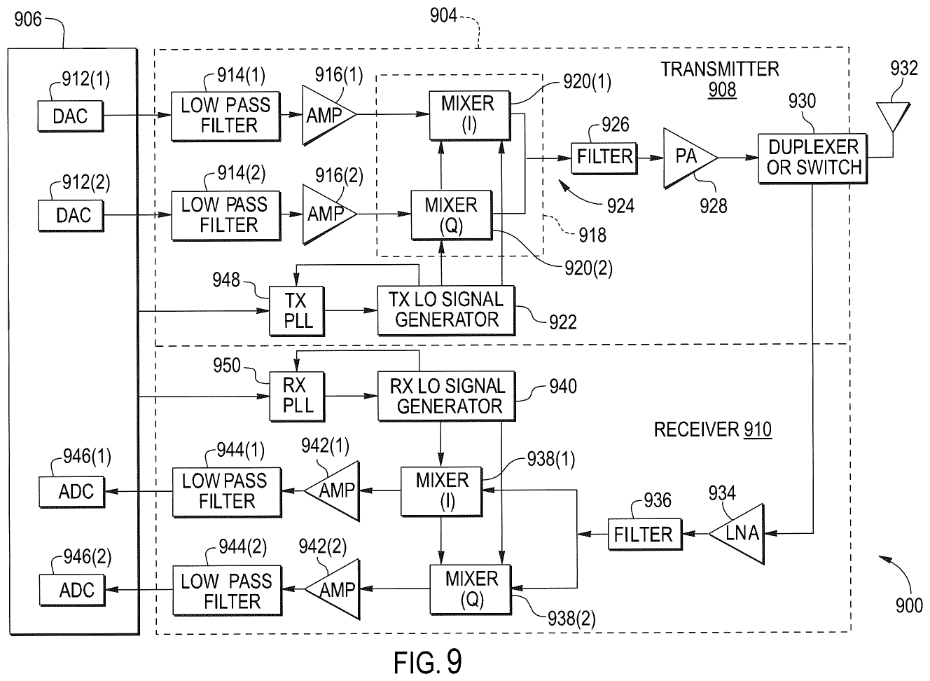

FIG. 9 is a block diagram of an exemplary wireless communications device that includes radio-frequency (RF) components deployed in an integrated circuit (IC) package, wherein the IC package includes an impure InP semiconductor substrate, including, but not limited to, the impure InP semiconductor substrates in FIGS. 2A and 3A and according to the exemplary fabrication processes in FIGS. 4, 5A-5C, and 7A-7C. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals (e.g., I and Q output currents) for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency up-conversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Down-conversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency up-conversion, while the RX LO signal generator 940 generates the I and Q RX LO signals used for frequency down-conversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

An impure InP semiconductor substrate as disclosed in aspects described herein may be provided in or integrated into an IC and deployed in any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

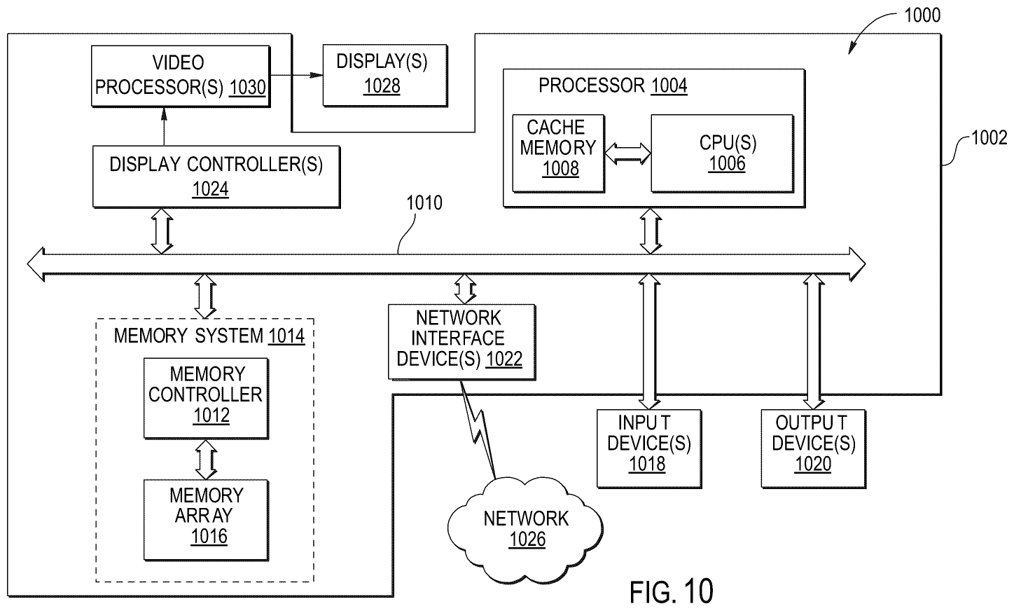

In this regard, FIG. 10 is a block diagram of an exemplary processor-based device 1000 that can include components deployed in an IC package(s) 1002, wherein the IC package includes an impure InP semiconductor substrate, including, but not limited to, the impure InP semiconductor substrates in FIGS. 2A and 3A and according to the exemplary fabrication processes in FIGS. 4, 5A-5C, and 7A-7C. In this example, the processor-based device 1000 includes a processor 1004 deployed on an InP semiconductor substrate that includes one or more central processing units (captioned as “CPUs” in FIG. 10) 1006, which may also be referred to as CPU cores or processor cores. The processor 1004 may have cache memory 1008 coupled to the processor 1004 for rapid access to temporarily stored data. The processor 1004 is coupled to a system bus 1010 and can intercouple server and client devices included in the processor-based device 1000. As is well known, the processor 1004 communicates with these other devices by exchanging address, control, and data information over the system bus 1010. For example, the processor 1004 can communicate bus transaction requests to a memory controller 1012, as an example of a client device. Although not illustrated in FIG. 10, multiple system buses 1010 could be provided, wherein each system bus 1010 constitutes a different fabric.

Other server and client devices can be connected to the system bus 1010 and deployed on an InP semiconductor substrate. As illustrated in FIG. 10, these devices can include a memory system 1014 that includes the memory controller 1012 and a memory array(s) 1016, one or more input devices 1018, one or more output devices 1020, one or more network interface devices 1022, and one or more display controllers 1024, as examples. The input device(s) 1018 can include any type of input device, including but not limited to input keys, switches, voice processors, etc. The output device(s) 1020 can include any type of output device, including, but not limited to, audio, video, other visual indicators, etc. The network interface device(s) 1022 can be any device configured to allow exchange of data to and from a network 1026. The network 1026 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1022 can be configured to support any type of communications protocol desired.

The processor 1004 may also be configured to access the display controller(s) 1024 over the system bus 1010 to control information sent to one or more displays 1028. The display controller(s) 1026 sends information to the display(s) 1026 to be displayed via one or more video processors 1030, which process the information to be displayed into a format suitable for the display(s) 1028. The display controller(s) 1024 and/or the video processors 1030 may comprise or be integrated into a GPU. The display(s) 1028 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A semiconductor substrate, comprising:
   a silicon layer defining a first width of the semiconductor substrate in a first direction; and
   an impure Indium Phosphide (InP) layer extending in the first direction along the first width of the semiconductor substrate, the impure InP layer adjacent to the silicon layer.
2. The semiconductor substrate of clause 1, wherein the impure InP layer comprises on the order of 10¹⁴ contaminants per cubic centimeter (cm³).
3. The semiconductor substrate of clause 2, wherein the on the order of 10¹⁴contaminants per cm³ comprises a compound selected from the group consisting of oxygen, carbon, and a hydride.
4. The semiconductor substrate of any of clauses 1-3, wherein the impure InP layer has a thickness in a second direction between 10-20 micrometers (μm).
5. The semiconductor substrate of any of clauses 1-4, wherein the first width of the semiconductor substrate is at least 200 millimeters (mm).
6. The semiconductor substrate of any of clauses 1-5, wherein the impure InP layer is bonded to the silicon layer.
7. The semiconductor substrate of any of clauses 1-6, wherein the silicon layer has a second width in a second direction of approximately 100 micrometers (μm).
8. The semiconductor substrate of any of clauses 1-7, further comprising:
   an intermediate layer between the silicon layer and the impure InP layer, comprising:
      a silicon dioxide (SiO₂) layer comprising a plurality of V-grooves separated by a plurality of shallow trench isolations; and
      an indium gallium arsenide (InGaAs) layer adjacent to the SiO₂ layer and grown in the plurality of V-grooves.
9. The semiconductor substrate of any of clauses 1-8, further comprising:
   a heterojunction transistor, comprising:
      a sub-collector layer directly adjacent to the impure InP layer;
      a collector layer directly adjacent to the sub-collector layer;
      a base layer directly adjacent to the collector layer;
      an emitter layer directly adjacent to the base layer; and
      an emitter cap layer directly adjacent to the emitter layer.
10. A method of fabricating a semiconductor substrate, comprising:
   providing a first silicon layer defining a first width of the semiconductor substrate in a first direction; and
   providing a first impure Indium Phosphide (InP) layer extending in the first direction along the first width of the semiconductor substrate, the first impure InP layer adjacent to the first silicon layer.
11. The method of clause 10, wherein providing the first impure InP layer extending in the first direction along the first width of the semiconductor substrate comprises:
   depositing a silicon dioxide (SiO₂) layer directly adjacent to a second silicon layer and patterning a plurality of trenches having a plurality of V-grooves in the SiO₂ layer and a top edge;
   epitaxially growing indium gallium arsenide (InGaAs) on the plurality of V-grooves to a height past the top edge of the plurality of trenches;
   epitaxially freestand growing the InGaAs to form a merged layer of the InGaAs that spans at least two of the plurality of trenches; and
   epitaxially growing InP to form a second impure InP layer having a desired thickness.
12. The method of clause 11, wherein the first silicon layer and the second silicon layer are a same silicon layer, and the first impure InP layer and the second impure InP layer are a same impure InP layer.
13. The method of clause 12, wherein the desired thickness is between 10-20 micrometers (μm).
14. The method of clause 11, wherein the desired thickness is at least 100 μm.
15. The method of clause 14, wherein providing the first impure InP layer extending in the first direction along the first width of the semiconductor substrate further comprises:
   cleaving a thin portion from the second impure InP layer, the thin portion defining the first impure InP layer; and
   bonding the first impure InP layer to the first silicon layer.
16. The method of any of clauses 11-15, wherein the first impure InP layer comprises at least 10¹⁴ contaminants per cubic centimeter (cm³).
17. The method of any of clauses 11-16, wherein the first width of the semiconductor substrate is at least 200 millimeters (mm).
18. A semiconductor substrate, comprising:
   means for providing a first silicon layer defining a first width of the semiconductor substrate in a first direction; and
   means for providing a first impure Indium Phosphide (InP) layer extending in the first direction along the first width of the semiconductor substrate, the first impure InP layer adjacent to the first silicon layer.
19. The semiconductor substrate of clause 18, wherein the means for providing the first impure InP layer extending in the first direction along the first width of the semiconductor substrate comprises:
   means for depositing a silicon dioxide (SiO₂) layer directly adjacent to a second silicon layer and patterning a plurality of trenches having a plurality of V-grooves in the SiO₂ layer and a top edge;
   means for epitaxially growing indium gallium arsenide (InGaAs) on the plurality of V-grooves to a height past the top edge of the plurality of trenches;
   means for epitaxially freestand growing the InGaAs to form a merged layer of the InGaAs that spans at least two of the plurality of trenches; and
   means for epitaxially growing InP to form a second impure InP layer having a desired thickness.
20. The semiconductor substrate of clause 19, wherein the first silicon layer and the second silicon layer are a same silicon layer, and the first impure InP layer and the second impure InP layer are a same InP layer.

What is claimed is:

1. A semiconductor substrate, comprising:
a silicon layer defining a first width of the semiconductor substrate in a first direction; and
an impure Indium Phosphide (InP) layer extending in the first direction along the first width of the semiconductor substrate, the impure InP layer adjacent to the silicon layer.

2. The semiconductor substrate of claim 1, wherein the impure InP layer comprises on the order of 10¹⁴ contaminants per cubic centimeter (cm³).

3. The semiconductor substrate of claim 2, wherein the on the order of 10¹⁴ contaminants per cm³ comprises a compound selected from the group consisting of oxygen, carbon, and a hydride.

4. The semiconductor substrate of claim 1, wherein the impure InP layer has a thickness in a second direction between 10-20 micrometers (μum).

5. The semiconductor substrate of claim 1, wherein the first width of the semiconductor substrate is at least 200 millimeters (mm).

6. The semiconductor substrate of claim 1, wherein the impure InP layer is bonded to the silicon layer.

7. The semiconductor substrate of claim 6, wherein the silicon layer has a second width in a second direction of approximately 100 micrometers (μm).

8. The semiconductor substrate of claim 1, further comprising:
an intermediate layer between the silicon layer and the impure InP layer, comprising:
a silicon dioxide (SiO₂) layer comprising a plurality of V-grooves separated by a plurality of shallow trench isolations; and
an indium gallium arsenide (InGaAs) layer adjacent to the SiO₂ layer and grown in the plurality of V-grooves.

9. The semiconductor substrate of claim 1, further comprising:
a heterojunction transistor, comprising:
a sub-collector layer directly adjacent to the impure InP layer;
a collector layer directly adjacent to the sub-collector layer;
a base layer directly adjacent to the collector layer;
an emitter layer directly adjacent to the base layer; and
an emitter cap layer directly adjacent to the emitter layer.

10. A method of fabricating a semiconductor substrate, comprising:
providing a first silicon layer defining a first width of the semiconductor substrate in a first direction; and
providing a first impure Indium Phosphide (InP) layer extending in the first direction along the first width of the semiconductor substrate, the first impure InP layer adjacent to the first silicon layer.

11. The method of claim 10, wherein providing the first impure InP layer extending in the first direction along the first width of the semiconductor substrate comprises:
depositing a silicon dioxide (SiO₂) layer directly adjacent to a second silicon layer and patterning a plurality of trenches having a plurality of V-grooves in the SiO₂ layer and a top edge;
epitaxially growing indium gallium arsenide (InGaAs) on the plurality of V-grooves to a height past the top edge of the plurality of trenches;
epitaxially freestand growing the InGaAs to form a merged layer of the InGaAs that spans at least two of the plurality of trenches; and
epitaxially growing InP to form a second impure InP layer having a desired thickness.

12. The method of claim 11, wherein the first silicon layer and the second silicon layer are a same silicon layer, and the first impure InP layer and the second impure InP layer are a same impure InP layer.

13. The method of claim 12, wherein the desired thickness is between 10-20 micrometers (μm).

14. The method of claim 11, wherein the desired thickness is at least 100 μm.

15. The method of claim 14, wherein providing the first impure InP layer extending in the first direction along the first width of the semiconductor substrate further comprises:
cleaving a thin portion from the second impure InP layer, the thin portion defining the first impure InP layer; and
bonding the first impure InP layer to the first silicon layer.

16. The method of claim 11, wherein the first impure InP layer comprises at least 10¹⁴ contaminants per cubic centimeter (cm³).

17. The method of claim 11, wherein the first width of the semiconductor substrate is at least 200 millimeters (mm).

18. A semiconductor substrate, comprising:
means for providing a first silicon layer defining a first width of the semiconductor substrate in a first direction; and
means for providing a first impure Indium Phosphide (InP) layer extending in the first direction along the first width of the semiconductor substrate, the first impure InP layer adjacent to the first silicon layer.

19. The semiconductor substrate of claim 18, wherein the means for providing the first impure InP layer extending in the first direction along the first width of the semiconductor substrate comprises:
means for depositing a silicon dioxide (SiO₂) layer directly adjacent to a second silicon layer and patterning a plurality of trenches having a plurality of V-grooves in the SiO₂ layer and a top edge;
means for epitaxially growing indium gallium arsenide (InGaAs) on the plurality of V-grooves to a height past the top edge of the plurality of trenches;
means for epitaxially freestand growing the InGaAs to form a merged layer of the InGaAs that spans at least two of the plurality of trenches; and
means for epitaxially growing InP to form a second impure InP layer having a desired thickness.

20. The semiconductor substrate of claim 19, wherein the first silicon layer and the second silicon layer are a same silicon layer, and the first impure InP layer and the second impure InP layer are a same InP layer.
